(19) United States
(12) Patent Application Publication
(10) Pub. No.: US 2002/0167804 A1
(43) Pub. Date: Nov. 14, 2002

(54) Polymeric encapsulation material with fibrous filler for use in microelectronic circuit packaging

(75) Inventor: Steven Towle, Phoenix, AZ (US)

Correspondence Address: Schwegman, Lunberg, Woessner & Kluth, P.A., P.O. Box 2938, Minneapolis, MN, 55402, US

(73) Assignee: Intel Corporation

(21) Appl. No.: 09/854,539

(22) Filed: May 14, 2001

(51) Int. Cl. H01F 3/04; H01F 7/06; H05K 1/18; H05K 3/30

(52) U.S. Cl. 361/765; 361/761; 29/841; 29/855

(57) ABSTRACT

An encapsulation material for use within a microelectronic device includes a polymeric base resin that is filled with a fibrous reinforcement material. The fiber reinforcement of the encapsulation material provides an enhanced level of crack resistance within a microelectronic device to improve the reliability of the device. In one embodiment, a fiber reinforced encapsulation material is used to fix a microelectronic die within a package core to form a die/core assembly upon which one or more metallization layers can be built. By reducing or eliminating the likelihood of cracks within the encapsulation material of the die/core assembly, the possibility of electrical failure within the microelectronic device (e.g., within the build up metallization layers) is also reduced.

### FIELD OF THE INVENTION

The invention relates generally to microelectronic devices and, more particularly, to techniques and materials for packaging such devices.

### BACKGROUND OF THE INVENTION

Many packaging techniques for microelectronic devices utilize encapsulation materials as a means to protect and/or support a microelectronic die within a package. It has been found, however, that some of these encapsulation materials are prone to cracking in regions of high stress within the package. High stress regions can be caused by, for example, mismatches in the coefficient of thermal expansion (CTE) of materials in the package. Cracks in the encapsulation material within a microelectronic device can have a devastating effect on overall device performance. Typically, the seriousness of a particular crack will depend upon the specific packaging approach being implemented. In one packaging technique, for example, an encapsulation material is used to fix a microelectronic die within a package core to form a die/core assembly. One or more metallization layers are then built up over the die/core assembly to complete the package. In devices manufactured in this manner, one or more cracks in the encapsulation material can lead to electrical failures within the device. As can be appreciated, a reduction in the occurrence and/or severity of such cracks can result in a significant increase in circuit reliability.

### BRIEF DESCRIPTION OF THE DRAWINGS

FIG. 1 is a simplified top view of a die/core assembly;

FIG. 2 is a sectional side view of the die/core assembly of FIG. 1;

FIG. 3 is a sectional side view of the die/core assembly of FIG. 1 after first and second metallization layers have been disposed thereon as part of a build up packaging process;

FIG. 4 is an exploded view of the die/core assembly of FIG. 1 illustrating the formation of a crack within the encapsulation material thereof;

FIGS. 5 and 6 are diagrams illustrating a process for dispensing fiber reinforced encapsulation material within a die/core assembly in accordance with one embodiment of the present invention;

FIG. 7 is a diagram illustrating a package core having channels in opposing corners of an opening therein for use in dispensing fiber reinforced encapsulation material;

FIG. 8 is an exploded view of FIG. 5 illustrating fiber alignment within an encapsulation material in accordance with one embodiment of the present invention;

FIG. 9 is a sectional side view of a microelectronic device having fillets formed from a fiber reinforced encapsulation material in accordance with one embodiment of the present invention;

FIG. 10 is a sectional side view of a microelectronic device having a globule of fiber reinforced encapsulation material disposed over a microelectronic die in accordance with one embodiment of the present invention; and

FIG. 11 is a sectional side view illustrating a portion of a microelectronic device that uses a Tessera® μBGA® type packaging scheme with the conventional elastomeric encapsulant replaced by a fiber reinforced encapsulation material in accordance with one embodiment of the present invention.

### DETAILED DESCRIPTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein in connection with one embodiment may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

The present invention relates to an encapsulation material having enhanced strength characteristics for use in the manufacture of microelectronic circuit devices. The encapsulation material includes a fibrous filler material dispersed within a polymeric resin base. The encapsulation material has flow properties that allow it to be injected into microelectronic package structures in a relatively simple manner. The fibers within the material provide an enhanced resistance to cracking even in regions of high mechanical stress. In one aspect of the invention, the encapsulation material is dispensed in a manner that aligns the fibers within the material in a direction that is perpendicular to the direction in which cracking is most likely to occur. The inventive principles can be used in connection with a wide variety of different circuit types and packaging techniques. The inventive principles are particularly beneficial when implemented in connection with packaging schemes that involve a build up of metallization layers on a microelectronic die/core assembly.

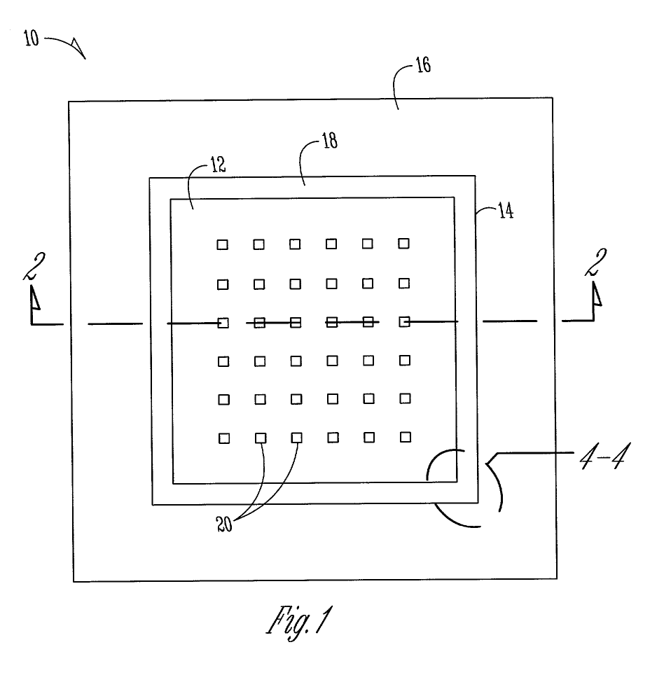

FIG. 1 is a simplified top view of a die/core assembly 10 that represents an intermediate stage in the manufacture of a packaged microelectronic device. As illustrated, a microelectronic die 12 is fixed within an opening 14 in a package core 16 using an encapsulation material 18. During package assembly, the die 12 is first positioned within the opening 14 in a desired orientation. A liquid or semi-liquid encapsulation material is then flowed into the gap between the die 12 and the package core 16 and allowed to harden (i.e., to cure). The hardened encapsulation material 18 serves to hold the die 12 in place within the package core 16 in a manner that allows one or more metallization layers to be subsequently formed over the assembly. The package core 16 can be formed from any of a wide range of different materials. Preferably, the material used for the package core 16 will be relatively rigid, although in at least one embodiment a more flexible material is used. Some possible materials for the core 16 include: bismaleimide triazine (BT), various resin-based materials, flame retarding glass/epoxy materials (e.g., FR4), polyimide-based materials, ceramic materials, metal materials (e.g., copper), and/or others. As shown, the die 12 has a plurality of bond pads 20 on an upper surface thereof that act as an electrical interface to the circuitry therein.

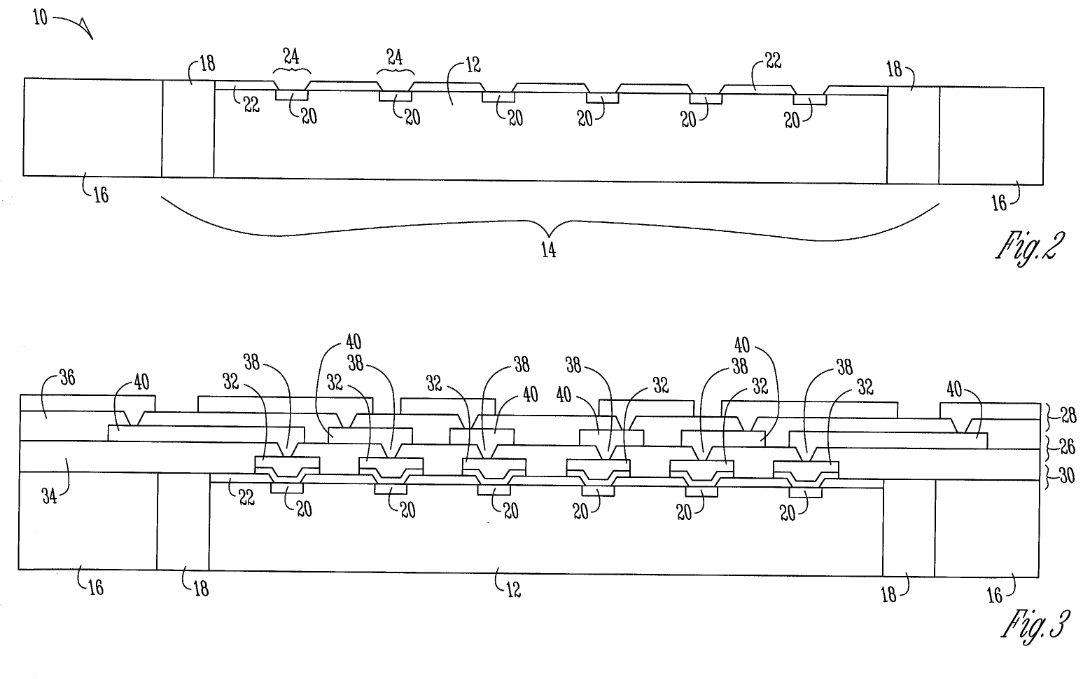

FIG. 2 is a sectional side view of the die/core assembly 10 of FIG. 1. As illustrated, the microelectronic die 12 is fixed within the opening 14 in the package core 16. The encapsulation material 18 fills the gap between the die 12 and the core 16. In the illustrated embodiment, the encapsulation material 18 is made flush with the upper surface of the die 12. Other arrangements are also possible. The die 12 has a passivation layer 22 covering an active surface thereof. Openings 24 are formed within the passivation layer 22 to expose the bond pads 20 therebelow. FIG. 3 is a sectional side view of the die/core assembly 10 of FIG. 1 after first and second metallization layers 26, 28 have been formed thereon. In the illustrated embodiment, an optional interfacial layer 30 has been developed directly on the passivation layer 22. The interfacial layer 30 includes a number of expanded bond pads 32 that are disposed above and conductively coupled to the bond pads 20 beneath the passivation layer 22. A first dielectric layer 34 is deposited over the interfacial layer 30. Via holes 38 are formed through the first dielectric layer 34 in locations corresponding to the expanded bond pads 32 of the interfacial layer 30. The first build up metallization layer 26 is then deposited over the first dielectric layer 34.

The first build up metallization layer 26 includes a number of conductive traces 40 that are conductively coupled to the expanded bond pads 32 of the interfacial layer 30 through corresponding via holes 38. A second dielectric layer 36 is then deposited and via holes are formed therein in locations corresponding to the conductive traces 40 of the first metallization layer 26. The second build up metallization layer 28 is then deposited over the second dielectric layer 36. As shown, by mounting the die 12 within the package core 16, the area over which build up metallization can be formed is increased significantly. In this manner, pitch expansion and escape routing can be provided for the microelectronic device. Any number of build up metallization layers can be used. Typically, an uppermost metallization layer will include, or be coupled to, the external contacts/leads of the package.

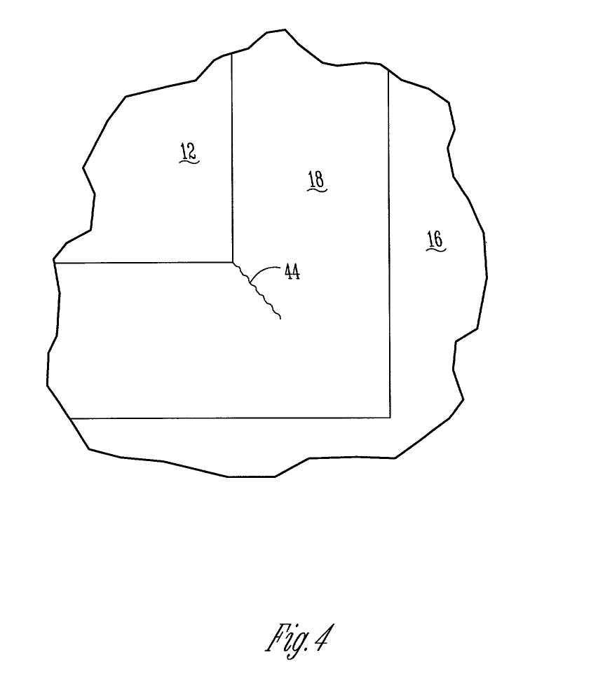

It was determined that cracking can occur within the encapsulation material 18 of a die/core assembly, such as the assembly 10 of FIG. 1. Typically, if cracks do form, they form in regions of high stress within the encapsulation material 18. One such high stress region exists at each of the corner points of the die 12. As the encapsulation material 18 hardens, stresses are created at the corner points of the die 12 due, in part, to differences between the coefficient of thermal expansion (CTE) of the encapsulation material 18 and the CTE of the die material (e.g., silicon). These stresses tend to form hairline cracks in the encapsulation material 18 in an outward direction from the die corner. Such hairline cracks can also form or be extended during subsequent use or during reliability testing of the packaged part. FIG. 4 is an exploded view of the die/core assembly of FIG. 1 illustrating such a crack 44 within the encapsulation material 18. As the encapsulation material 18 forms part of the base upon which addition metallization layers will be built, any cracking within the material 18 can have a devastating effect on circuit integrity and can lead to electrical failure. Thus, it is important to reduce or eliminate the occurrence of such cracks.

In accordance with at least one embodiment of the present invention, a fiber reinforced encapsulation material is used to fix a microelectronic die 12 within a package core 16. The fiber reinforced encapsulation material includes a polymeric resin base that is filled with a fibrous reinforcement material. The fibrous reinforcement material adds strength to the resin and thus enhances the resistance to cracking of the composite material. The polymeric resin can include, for example, various plastics or epoxies. For example, in one embodiment, a Bis-phenol F epoxy (Diglycidyl ether of Bis-phenol F) and Anhydride are used with a catalyst such as immidazole. In another embodiment, a liquid epoxy including Bis-phenol F with an immidazole catalyst is used. In yet another embodiment, a liquid epoxy including Bis-phenol F with a multi-phenol as a hardener and triphenyl phosphine (TPP) as a catalyst is used. Other epoxy formulations are also possible. Other resin materials can also be used including, for example, silicone based resin materials (e.g., alkylsiloxane polymer), cyanate ester based materials (available from Honeywell), bismaleimide based materials (available from Dexter/Quantum), and others. Any of the various materials commonly used to provide underfill, dam, or fillet functions within a microelectronic device can be used as the polymeric base resin. The polymeric resin material may also include additives (e.g., wetting agents, deflocculating agents, adhesions promoters, etc) such as those commonly used in applications involving filler materials.

The fibrous reinforcement material can include any material having fibers of an appropriate size and strength. This can include, for example, glass fibers, ceramic fibers, carbon fibers (e.g., graphite), Kevlar® fibers, metal fibers (e.g., steel), and others. In one embodiment, fibers having a length between 5 and 40 micrometers and a diameter between 0.5 and 5 micrometers are used, although other fiber sizes are also possible. The length to width ratio of the individual fibers will typically be 5 or greater. To form the fiber reinforced encapsulation material, the fibrous reinforcement material need only be mixed into the polymeric resin base material in an appropriate ratio. The ratio that is used (and also the type of fiber) will typically depend upon the amount of strengthening that is desired in a particular application.

The fiber reinforced encapsulation material can be dispensed in any manner that encapsulation materials are normally dispensed. In one approach, for example, the material is injected into the gap between the die 12 and the core 16 using a needle or similar device. Because the fiber reinforced material will typically be more viscous than a conventional encapsulation material, modifications to the dispensing process may be required to accommodate the thicker material. For example, thicker needles or dispensing heads may be required. Similarly, gap dimensions within the microelectronic assembly may need to be increased to permit adequate flow of the viscous composite material.

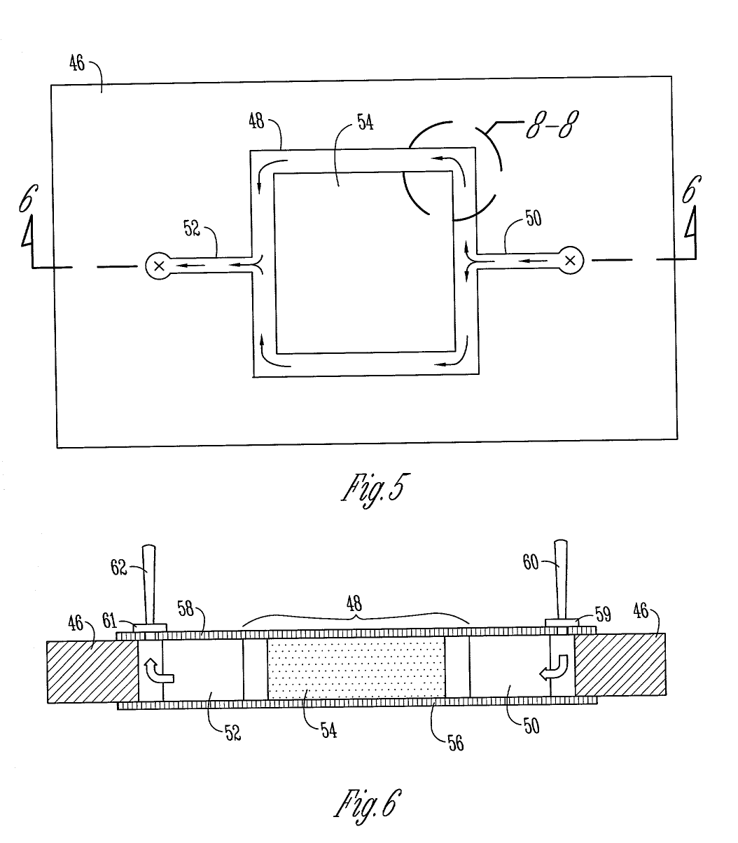

FIGS. 5 and 6 illustrate a technique for dispensing fiber reinforced encapsulation material within a die/core assembly in accordance with one embodiment of the present invention. One advantage of this technique is its ability to provide void free encapsulation using highly viscous materials (e.g., ≧500,000 centipoise). A package core 46 is provided that has an opening 48 therein to receive a microelectronic die 54, as described above. The package core 46 also includes a pair of channels 50, 52 that are in fluid communication with the opening 48. As illustrated in FIG. 6, a first protective film 56 is adhered to a lower surface of the package core 46 to fully cover the opening 48 and the channels 50, 52. In one embodiment, the first protective film 56 is formed from a Kapton® polyimide film available from E.I. du Pont de Nemours and Company of Wilmington, Del. It should be appreciated, however, that the first protective film 56 can be made out of any appropriate material including, for example, metallic film materials. Preferably, the first protective film 56 will have a CTE that is the same as or similar to the CTE of the material of the package core 46. The adhesive is preferably a material that is thermally and chemically compatible with the encapsulant and the other materials of the die/core assembly. For example, in the case of an epoxy based encapsulant, a heat resistant silicone adhesive may be used.

After the first protective film 56 has been applied, a microelectronic die 54 is positioned within the opening 48 of the package core 46. In one approach, the upper surface of the first protective film 56 has an adhesive material thereon that holds the die 54 in the appropriate position during subsequent processing. After the die 54 is in place, a second protective film 58 is adhered to an upper surface of the package core 46 over the opening 48 and the channels 50, 52. The second protective film 58 will also preferably adhere to the upper surface of the die 54. The second protective film 58 can be formed from the same material as the first protective film 56 or a different material. Holes are formed through the second protective film 58 in locations corresponding to the distal ends of the channels 50, 52 for use in dispensing the encapsulation material. The holes can be formed either before or after the second protective film 58 is applied. A dispensing needle 60 with attached sealing nipple 59 is placed over the hole in the protective film 58 corresponding to the first channel 50. Similarly, a vacuum needle 62 with attached sealing nipple 61 is placed over the hole in the protective film 58 corresponding to the second channel 52. The sealing nipples 59, 61 will each preferably form a relatively air tight seal about the corresponding hole during the dispensing process. In an alternative approach, the needles 60, 62 are inserted through the holes in the second protective film 58 without the use of sealing nipples.

As shown in FIG. 6, the dispensing needle 60 injects the fiber reinforced encapsulation material (in a fluid form) into the first channel 50. With reference to FIG. 5, the fiber reinforced encapsulation material flows through the first channel 50 toward the die 54 and then separates into two streams that flow around the periphery of the die 54. The two streams eventually meet up on the other side of the die 54 and flow into the second channel 52. The vacuum needle 62 creates a vacuum within the assembly that facilitates the flow of material through the assembly. The vacuum can also help to hold the first and second protective films 56, 58 against the die 54 during the dispensing process. After the fiber reinforced encapsulation material has been fully dispensed, the material is allowed to cure. The first and second protective films 56, 58 are then removed. If required, the cured encapsulation material can then be planarized (e.g., by grinding) to make it flush with the surface of the die 54 and/or the core 46. Preferably, the cured encapsulation material will be sufficiently planar at the upper and lower surface of the core 46 after the protective films 56, 58 have been removed so that additional planarization is not required.

In an alternative approach, the above described dispensing technique is practiced without vacuum assistance. That is, the vacuum needle 62 is not used and a hole is simply provided in the second protective film 58 at the end of the second channel 52 to allow air or other gases to escape during the dispensing process. The above described technique can also be performed without separate channels 50, 52 within the core 46. The channels 50, 52, however, have been found to improve the flow of material through the assembly. In addition, if there are any defects associated with the needle insertion point for a particular microelectronic device, these defects will be located at a position that is less likely to cause harm within the completed device when channel are used. Because the location of needle insertion is known, traces on the first build up metallization layer of a microelectronic device can be routed around these potential defect locations to improve reliability.

The channels 50, 52 do not have to be located along the sides of the opening 48, as shown in FIG. 5. For example, FIG. 7 illustrates a package core 46 having channels 50, 52 in opposing corners of the opening 48. This arrangement may actually be preferred when a vacuum assisted process is being implemented because it helps prevent the formation of “zones of zero net flow” within the assembly. Zones of zero net flow can form when a single stream of encapsulation material is split into two streams flowing in substantially opposite directions or when two streams flow toward each other and meet head on. Zones of zero net flow can result in voids in the encapsulation material and are therefore undesirable. As described previously, the channels 50, 52 and the opening 48 must be sized to allow a free flow of the relatively viscous fiber reinforced encapsulation material. In one embodiment, a trench between the die 54 and the package core 46 is formed that is approximately 1 millimeter wide by 1 millimeter deep. The dimensions that are used in a particular implementation will depend upon the resin and fiber materials that are being utilized, as well as the concentration of fiber within the resin and the thickness of the other elements, such as the die and the substrate. Still other patterns of flow are possible and may need to be implemented in, for example, the case of a multi-chip module with multiple dice to be co-embedded in the same cavity.

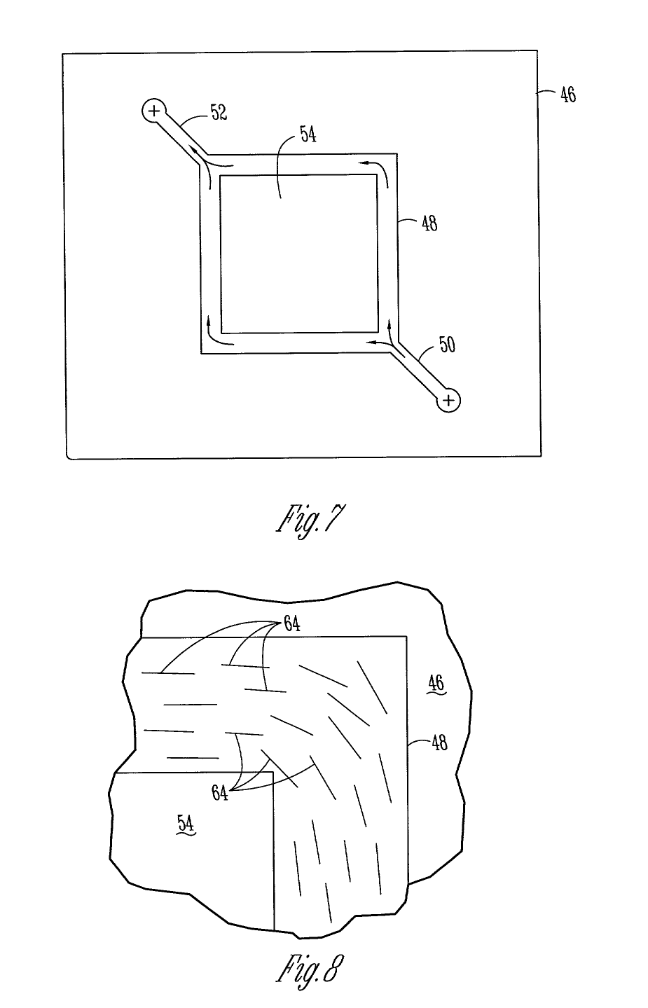

It has been observed that the fibers within a flowing encapsulation material will tend to align themselves with the direction of fluid flow. In the dispensing technique illustrated in FIGS. 5 and 6, this property has been taken advantage of to provide enhanced strength within the encapsulation material in the regions of highest stress (e.g., at the corners of the die 54). FIG. 8 is an exploded view of the assembly of FIG. 5 illustrating this feature. As shown, the fibers 64 within the encapsulation material align themselves about the periphery of the die 54 in the direction of fluid flow. Thus, at the corners of the die 54, the fibers 64 are oriented in a manner that will resist the formation of cracks that radiate outward from the corner (such as crack 44 of FIG. 4). This dispensing technique can be used in any area where cracks are likely to form (i.e., high stress areas) by arranging the fluid flow of the fiber reinforced encapsulation material to be approximately perpendicular to the anticipated direction of crack formation.

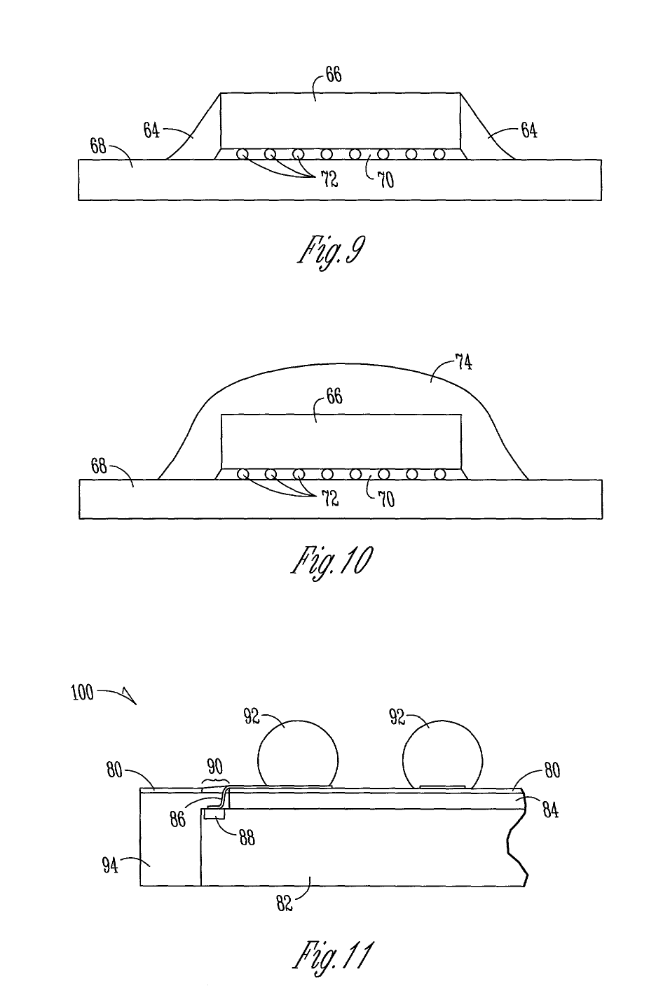

The fiber reinforced encapsulation material of the present invention has many other applications related to the fabrication of microelectronic devices. For example, as shown in FIG. 9, the fiber reinforced encapsulation material can be used to form fillets 64 about a microelectronic die 66 that is mounted on a substrate 68, to increase the structural integrity of the assembly. As the viscosity of the fiber reinforced encapsulation material will typically be relatively high, it may not be appropriate for use as an underfill material for the die 66. Thus, a conventional (non-fiber reinforced) underfill material 70 can be used to fill the regions about the contacts 72 of the die 66. As shown in FIG. 10, the fiber reinforced encapsulation material can also be used in glob top applications to form a globule 74 of encapsulant over a microelectronic die 66.

In yet another application, a fiber reinforced encapsulation material is used within a Tessera® μBGA® type package. FIG. 11 is a sectional side view illustrating a portion of a microelectronic device 100 having such a package. The Tessera® μBGA® is a packaging scheme that utilizes compliant materials to overcome many of the reliability problems often associated with CTE mismatch within microelectronic devices. In a typical μBGA® process, a flexible circuit board 80 (e.g., polyimide tape) is first bonded to a carrier frame. Multiple microelectronic dice 82 are then attached to a first side of the flexible circuit board 80 in predetermined locations. The flexible circuit board 80 has an elastomer pad 84 (or a similar elastomer structure or structures) on the first side thereof in each of the die locations to provide a compliant buffer between each die 82 and the flexible board 80. After the dice 82 have been attached to the flexible board 80, a bonder tool is used to connect a bond ribbon 86 from each of the bond pads 88 of the dice 82 to the flexible circuit board 80. Typically, this ribbon bonding is done from a second side of the flexible circuit board 80 (i.e., a side opposite the first side) through openings 90 in the board 80.

An encapsulation mask is then applied to the second side of the flexible circuit board 80 to cover the openings 90. An encapsulation material 94 is then dispensed about and between each die 82 on the first side of the flexible circuit board 80 to surround each die 82 and its corresponding bond ribbons 86. The encapsulation material 94 solidifies to form a protective barrier about the bond ribbons 86 and the dice 82 that enhances the structural integrity of the assembly. Solder balls 92, or other contact structures, are then attached in predetermined locations on the second side of the flexible circuit board 80 to provide an external electrical interface to the circuitry of the die 82. The solder balls 92 are each conductively coupled to a corresponding bond pad 88 on the associated die 82 through one of the bond ribbons 86. The entire assembly is then divided up into a plurality of individual packaged dice, such as the die 100 of FIG. 11.

In a conventional μBGA® process, an elastomeric encapsulation material (e.g., silicone rubber) is used to give the microelectronic device better resistance to mechanical stresses caused by, for example, CTE mismatches. In accordance with at least one embodiment of the present invention, a fiber reinforced encapsulation material 94 is used within a μBGA®-like packaging process to form microelectronic devices. The fiber reinforcement of the encapsulation material 94 provides the toughness required by the μBGA® style package without the reliability concerns often associated with elastomeric encapsulation materials. In at least one approach, a fiber reinforced encapsulation material is dispensed within a μBGA®-like packaging process using a vacuum assisted dispensing technique, such as the one described previously.

Although FIGS. 1-11 illustrate various views and embodiments of the present invention, these figures are not meant to portray microelectronic assemblies in precise detail. For example, these figures are not typically to scale. Rather, the figures illustrate microelectronic assemblies in a manner that is believed to more clearly convey the concepts of the present invention.

Although the present invention has been described in conjunction with certain embodiments, it is to be understood that modifications and variations may be resorted to without departing from the spirit and scope of the invention as those skilled in the art readily understand. Such modifications and variations are considered to be within the purview and scope of the invention and the appended claims.

What is claimed is:

1. A microelectronic device comprising:
a package core having an opening therein;
a microelectronic die located within the opening of said package core; and
a fiber reinforced encapsulation material within the opening of said package core to hold said microelectronic die within said package core, said fiber reinforced encapsulation material including a polymeric resin having a fibrous filler material.

2. The microelectronic device of claim 1, wherein:
said fibrous filler material includes individual fibers having a length between 1 micrometer and 40 micrometers.

3. The microelectronic device of claim 1, wherein:
said fibrous filler material includes individual fibers having a length to width ratio that is no less than 5.

4. The microelectronic device of claim 1, wherein:
said fibrous filler material includes glass fibers.

5. The microelectronic device of claim 1, wherein:
said fibrous filler material includes carbon fibers.

6. The microelectronic device of claim 1, wherein:
said fibrous filler material includes Kevlar® fibers.

7. The microelectronic device of claim 1, wherein:
said fibrous filler material includes ceramic fibers.

8. The microelectronic device of claim 1, wherein:
said fibrous filler material includes metal fibers.

9. The microelectronic device of claim 1, wherein:
said polymeric resin includes epoxy.

10. The microelectronic device of claim 1, wherein:
said polymeric resin includes plastic.

11. The microelectronic device of claim 1, comprising:
at least one metallization layer built up over said package core, said at least one metallization layer being conductively coupled to bond pads on a surface of said microelectronic die.

12. A microelectronic device comprising:
a package substrate;
a microelectronic die mechanically coupled to said package substrate, said microelectronic die having a plurality of electrical contacts that are conductively coupled to contacts on said package substrate; and
a fiber reinforced encapsulation material mechanically coupled to said microelectronic die to provide structural support for said microelectronic die, said fiber reinforced encapsulation material including a polymeric resin having a fibrous filler material.

13. The microelectronic device of claim 12, wherein:
said fiber reinforced encapsulation material forms a fillet between said microelectronic die and said package substrate.

14. The microelectronic device of claim 12, wherein:
said fiber reinforced encapsulation material forms a globule covering said microelectronic die.

15. The microelectronic device of claim 12, wherein:
said package substrate includes a flexible circuit board.

16. The microelectronic device of claim 15, wherein:
said fiber reinforced encapsulation material fills a region between said microelectronic die and said flexible circuit board.

17. The microelectronic device of claim 12, wherein:
said fibrous filler material includes individual fibers having a length between 1 micrometer and 40 micrometers and a length to width ratio that is no less than 5.

18. A method for manufacturing a microelectronic device comprising:
providing a package core having an opening therein;
positioning a microelectronic die within the opening in said package core; and
dispensing a fiber reinforced encapsulation material into said opening in said package core to fill a gap between said microelectronic die and said package core, said fiber reinforced encapsulation material including a polymeric resin having a fibrous filler material.

19. The method of claim 18, wherein:
dispensing a fiber reinforced encapsulation material includes creating a flow of encapsulation material about said microelectronic die in a direction that is approximately perpendicular to a direction of anticipated crack formation.

20. The method of claim 19, wherein:
said direction of anticipated crack formation is an outward direction from a corner of said microelectronic die.

21. The method of claim 18, wherein:
said package core includes a first channel in fluid communication with said opening, wherein dispensing a fiber reinforced encapsulation material includes injecting said fiber reinforced encapsulation material into said first channel.

22. The method of claim 21, wherein:
said package core includes a second channel in fluid communication with said opening, wherein dispensing a fiber reinforced encapsulation material includes creating a partial vacuum within said second channel.

23. The method of claim 18, comprising:
applying a first protective film over a first surface of said package core before dispensing said fiber reinforced encapsulation material, said first protective film covering said opening in said package core.

24. The method of claim 23, comprising:
applying a second protective film over a second surface of said package core before dispensing said fiber reinforced encapsulation material, said second protective film covering said opening in said package core.
